(19) United States
(12) Patent Application Publication
(10) Pub. No.: US 2014/0034112 A1
(43) Pub. Date: Feb. 6, 2014

(54) OPTICAL CONCENTRATORS AND SPLITTERS

(71) Applicants: Scott Lerner, Portland, OR (US); Stephan R. Clark, Albany, OR (US); John P. Whitlock, Lebanon, OR (US)

(72) Inventors: Scott Lerner, Portland, OR (US); Stephan R. Clark, Albany, OR (US); John P. Whitlock, Lebanon, OR (US)

(21) Appl. No.: 14/112,920

(22) PCT Filed: May 26, 2011
(86) PCT No.: PCT/US2011/038055

§ 371 Date: Oct. 19, 2013

(51) Int. Cl. G02B 27/14; H01L 31/052

(52) U.S. Cl. CPC G02B 27/142; H01L 31/0525
USPC 136/246; 359/618; 359/629; 359/361; 359/350; 438/65

(57) ABSTRACT

Apparatus and methods are provided for use with solar energy. An optical concentrator and splitter (OCS) includes a non-planar bottom surface having symmetrical halves, each half defined by an off-axis section of a parabola. The bottom surface bears a dielectric surface treatment. The OCS is configured to concentrate a first spectral portion of photonic energy through respective side surfaces, and to concentrate a second spectral portion through the bottom surface. Targets such as photovoltaic cells or others receive the concentrated first and second spectral portions, respectively.

### STATEMENT OF GOVERNMENT INTEREST

The invention that is the subject of this patent application was made with Government support under Subcontract No. CW135937, under Prime contract No. HR0011-07-9-0005, through the Defense Advanced Research Projects Agency (DARPA). The Government has certain rights in this invention.

### BACKGROUND

Solar energy devices and apparatus make use of incident sunlight to heat eater or other fluids, for direct conversion to electrical energy, and so on. Improvements in solar energy capture, energy transfer or conversion efficiency within such devices and systems is constantly sought after. The present teachings address the foregoing and other concerns.

### BRIEF DESCRIPTION OF THE DRAWINGS

The present embodiments will now be described, by way of example, with reference to the accompanying drawings, in which:

FIG. 1 is an end elevation view of an optical concentrator and splitter according to one example of the present teachings;

FIG. 2 is an isometric-like view of an apparatus according to another example of the present teachings;

FIG. 3 is an end elevation view of an optical concentrator and splitter according to another example;

FIG. 4 is an end elevation view of an optical concentrator and splitter according to yet another example;

FIG. 5 is a block diagram of a system according to another example of the present teachings;

FIG. 6 is a flow diagram of method according to an example of the present teachings.

### DETAILED DESCRIPTION

### Introduction

Apparatus and methods are provided for use with solar energy. An optical concentrator and splitter (OCS) includes a planar bottom surface having symmetrical halves, each half being defined by an off-axis section of a parabola. The bottom surface bears dielectric surface treatment. The OCS is configured to concentrate a first spectral portion of photonic energy through respective side surfaces, and to concentrate a second spectral portion through the bottom surface. Targets such as photovoltaic cells or other entities receive the concentrated first and second spectral portions, respectively.

In one example, an apparatus includes a solid optical material formed to define a top surface and a pair of opposite side surfaces and a non-planar bottom surface. The apparatus also includes one or more dielectric materials applied to the non-planar bottoms surface so as to define a coated bottom surface. The apparatus is configured to receive photonic energy through the top surface and to concentrate a first spectral band of that photonic energy through the opposite side surfaces. The apparatus is further configured to concentrate a second spectral band of the photonic energy through the coated bottom surface.

In another example, a solar energy device includes an optical concentrator and splitter formed from a solid optical material. The optical concentrator and splitter is configured to concentrate a first spectral band of photonic energy onto a pair of first target locations. The optical concentrator and splitter is also configured to concentrate a second spectral band of photonic energy onto a second target location distinct from the first target location. The solar energy device also includes photovoltaic cells disposed at the first target locations, and photovoltaic cells disposed at the second target location.

In yet another example, a method includes forming a solid optical material to define a top surface and a non-planar bottom surface and a pair of opposite side surfaces. The method also includes forming a surface treatment of dielectric material on the bottom surface so as to define a coated surface. The method also includes, in one embodiment, supporting respective photovoltaic cells parallel to each of the side surfaces. The method further includes supporting photovoltaic cells beneath and spaced apart from the bottom surface.

### First Illustrative Optical Concentrator and Splitter

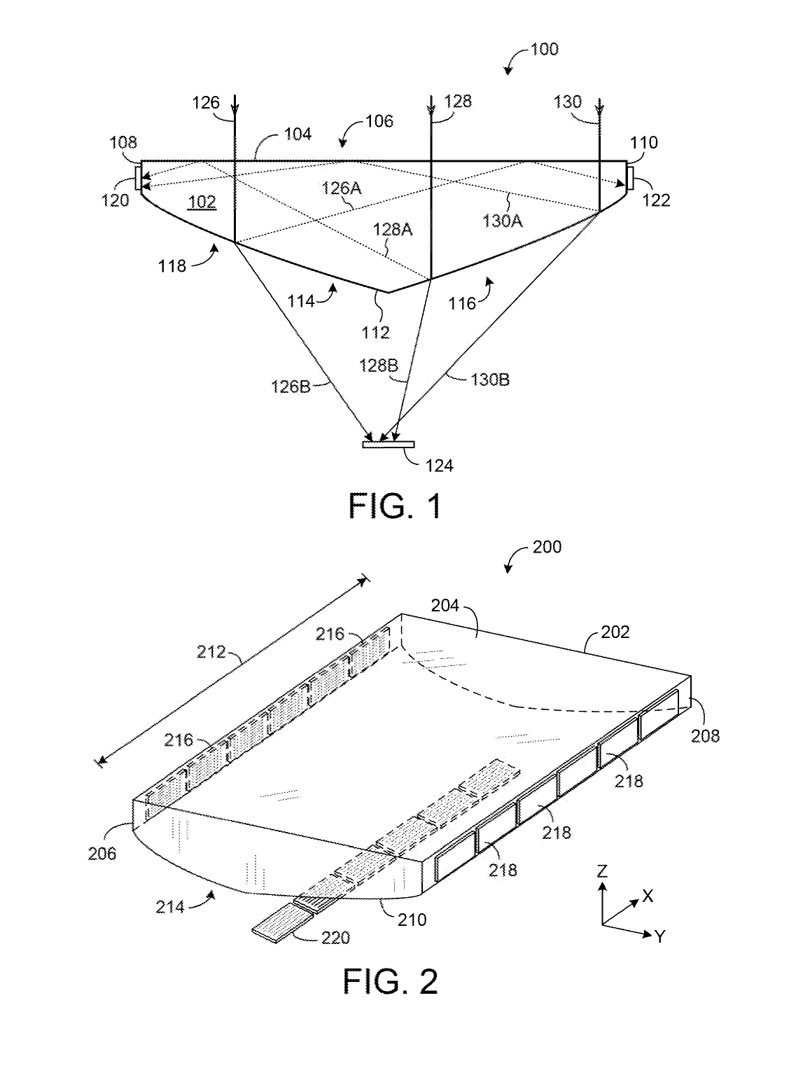

Reference is now directed to FIG. 1 which depicts an end elevation vie, of an optical concentrator (concentrator) 100. The concentrator 100 is illustrative and non-limiting with respect to the present teachings. Thus, other optical concentrators, apparatus, devices or systems can be configured and/or operated accordance with the present teachings. For purposes herein, the concentrator 100 can also be referred to a an optical concentrator and splitter (OCS) 100.

The concentrator 100 is formed from a solid optical material 102 such as glass, quartz, optical plastic, and so on. Other suitable materials can also be used. The concentrator 100 includes a cross-section that is geometrically and dimensionally constant throughout at least a portion of a lengthwise aspect (i.e., extending into the page as seen by the viewer), and which is devoid of internal cavities, pockets, apertures, surface intrusions, or the like. In one example, the solid optical material 102 is formed from glass having a refractive index of about 1.5

The concentrator 100 includes or is defined by a top surface 104. The top surface 104 is planar in form. The concentrator 100 can optionally include a top surface treatment 106 borne by or formed upon the top surface 104. The top surface treatment 106 can be defined by an infrared (IR) blocking surface treatment, are ultra-violet (UV) blocking surface treatment, an anti-reflective surface treatment, and so on. Other suitable surface treatments 106 can also be used. The concentrator 100 also includes or is defined a pair of opposite side surfaces 108 and 110, respectively. The respective side surfaces 108 and 110 can be planar and parallel to each other. Each of the side surfaces 108 and 110 can also be orthogonal to the top surface 104.

The concentrator 100 also includes a bottom surface 112. The bottom surface 112 is also referred to as a non-planar bottom surface 112 and is defined by bilateral symmetry. That is, the bottom surface 112 is defined by two symmetrical halves 114 and 116, respectively. Each of the half portions 114 and 116 is characterized by a cross-sectional curate or surface contour defined by an off-axis section of a parabola.

The concentrator 100 also includes a bottom surface treatment 118 borne by or formed upon the bottom surface 112. The bottom surface treatment 118 is formed from one or more layers of dielectric material. One or more respective dielectric materials can be used. Non-limiting examples of dielectric materials include silicon dioxide (SiO₂), niobium pentoxide (Nb₂O₅), titanium dioxide (TiO₂), tantalum pentoxide (Ta₂O₅), zirconium pentoxide (Zr₂O₅), hafnium dioxide (HfO₂), magnesium fluoride (MgF₂), aluminum oxide (Al₂O₃), and so on. Other suitable materials can also be used.

Thus, the bottom surface treatment 118 can be variously defined in accordance with the desired operating characteristics of the concentrator 100. The present teachings contemplate the use of various dielectric materials arranged as respective layers so as to define various bottom surface treatments 118. In one example, two different dielectric species are arranged as a total of thirty-six alternating layers (eighteen layers of each species). The bottom surface 112 is also referred to as a coated bottom surface 112 by virtue of the bottom surface treatment 118.

The surface treatment 118 is configured to reflect a spectral portion or band of photonic energy that is incident to the concentrator 100 during normal operation. The bottom surface treatment 118 is further configured to pass another spectral portion or band of photonic energy through the bottom of the concentrator 100. Such distinct spectral portions are referred to herein as a first spectral portion (or band) and a second spectral portion (or band), respectively.

Also included is a photovoltaic cell 120 that is supported in contact with or near to the side surface 108 of the concentrator 100. Additionally, a photovoltaic cell 122 is supported in contact with or near to the side surface 110 of the concentrator 100. Furthermore, a photovoltaic cell 124 is disposed below the bottom side 112 of the concentrator 100 and spaced away there from. Each of the photovoltaic cells 120-124, respectively, is configured to generate electrical energy by direct conversion of photonic energy.

Normal, illustrative operation of the concentrator 100 is generally as follows: Photonic energy, in the form of sunlight or another radiant emission, is incident to the top surface 104 of the concentrator 100. Three illustrative beams 126, 128 and 130, respectively, are depicted in the interest of clarity. However, it is to be understood that the entire top surface 104 is exposed to such photonic energy during normal operations. The respective beams 126-130 pass through the top surface 104 and are subject to any top surface treatment 106 that is borne thereon, and into the solid material 102 of the concentrator 100.

Each of the beams 126-130 strikes the inside face of the bottom surface 112 at a respective location as depicted. A first spectral band of the photonic energy is reflected away from the bottom surface 112 by virtue of the bottom surface treatment 118. As depicted, a first spectral portion 126A of the beam 126 is internally reflected away from the bottom surface 112, off of the inside of the top surface 104 and through the side surface 110. In turn, the first spectral portions 128A and 130A, respectively, of the beams 128 and 130 are similarly internally reflected to the side surface 108. In one example this first spectral band is defined by photonic energy from about four-hundred nanometers to about eight-hundred fifty nanometers in wavelength. Other first spectral bands can also be defined.

A second spectral band of the photonic energy passes through the bottom surface 112 and the bottom surface treatment 118 and is refracted toward a target location. In one example, this second spectral band is defined by photonic energy from about eight-hundred fifty-one nanometers to about eighteen-hundred nanometers ire wavelength. Other second spectral bands can also be defined. In one example, the average wavelength of the first spectral band is lesser than the average wavelength of the second spectral band, wherein the first and second spectral bands represent mid-energy and low-energy bands, respectively.

The photovoltaic cell 120 is disposed to receive the first spectral band (or portion) 128A and 130A of the beams 128 and 130, respectively. The photovoltaic cell 122 is disposed to receive the first spectral band 26A of the beam 126. In turn, the photovoltaic cell 124 is disposed to receive the second spectral band 126B 128B and 130B, respectively, of the beams 126, 128 and 130. The photovoltaic cells 120, 122 and 124 can be individually selected in accordance with the spectral bandwidth that each is exposed to during normal operations. In this way, photovoltaic cells or other target entities can be optimally selected in accordance with the particular characteristics of the concentrator 100.

### Illustrative Apparatus

Attention is nova turned to FIG. 2, which depicts an isometric-like view of an apparatus 200 in accordance with another example of the present teachings. The apparatus 200 is illustrative and non-limiting with respect to the present teachings. Other devices, apparatus and systems can also be used

The apparatus 200 includes an optical concentrator and splitter (OCS) 202. The OCS 202 is formed from a solid, void-less optical material such as optical plastic, glass, or another suitable material. The OCS 202 is defined by a planar top surface 204, opposite side surfaces 206 and 208, respectively, and a non-planar, bilaterally symmetrical bottom surface 210. Each half of the bottom surface 210 is defined by a cross-sectional shape in accordance with an off-axis section of a parabola. As such, the OCS 202 has a constant cross-sectional shape along a lengthwise aspect 212. In one example, the lengthwise aspect 212 is ten centimeters. Other dimensions can be used.

The OCS 202 includes a bottom surface treatment 214 overall the bottom surface 210 area. The bottom surface treatment 214 can be applied or formed using one or more dielectric materials such as those illustrative materials described above. The bottom surface treatment 214 functions to define a first spectral band (i.e., relatively higher energy) that is internally reflected within the OCS 202. The bottom surface treatment 214 further defines a second spectral band (i.e., relatively lower energy) that passes through the bottom surface 210 and the bottom surface treatment 214. In one example, the OCS 202 is substantially equivalent to the concentrator 100 described above.

The apparatus 100 also includes a plurality of photovoltaic cells 216 disposed along the side surface 206. The photovoltaic cells 216 are arranged to face inward toward the OCS 202 and to receive a first spectral band of photonic energy by way of internal reflections. The apparatus 100 also includes a plurality of photovoltaic cells 218 disposed along the side surface 208. The photovoltaic cells 218 are arranged to face inward toward the OCS 202 and to receive a first spectral band of photonic energy.

The apparatus 100 further includes a plurality of photovoltaic cells 220 arranged to receive a second spectral band of photonic energy by way of refraction of the OCS 202 and pass-band operation of the bottom surface treatment 214. Support for the respective photovoltaic cells 216, 218 and 228 can be provided by way of epoxy, mechanical supports, and the like—the specific definition or form of such supports is not germane to the present teachings.

In one example, an OCS 202 is defined by a lengthwise dimension (“X” axis) of ten centimeters, a widthwise dimension (“Y” axis) of ten centimeters, and minimum and maximum thickness dimensions (“Z” axis) of one and three centimeters, respectively. It is to be understood that “X” “Y” and “Z” are mutually orthogonal axis, as depicted. Other respective dimensions can also be used. Such an OCS 202 can be formed from optical plastic having a refractive index of about 1.49. In one example, the OCS 202 is characterized by a first spectral band (i.e., higher energy) concentration ratio of about thirty times by way of internal reflections, and second spectral band (i.e., lower energy) concentration ratio of about eight times. Other respective concentration ratios are also contemplated.

### Second Illustrative Optical Concentrator and Splitter

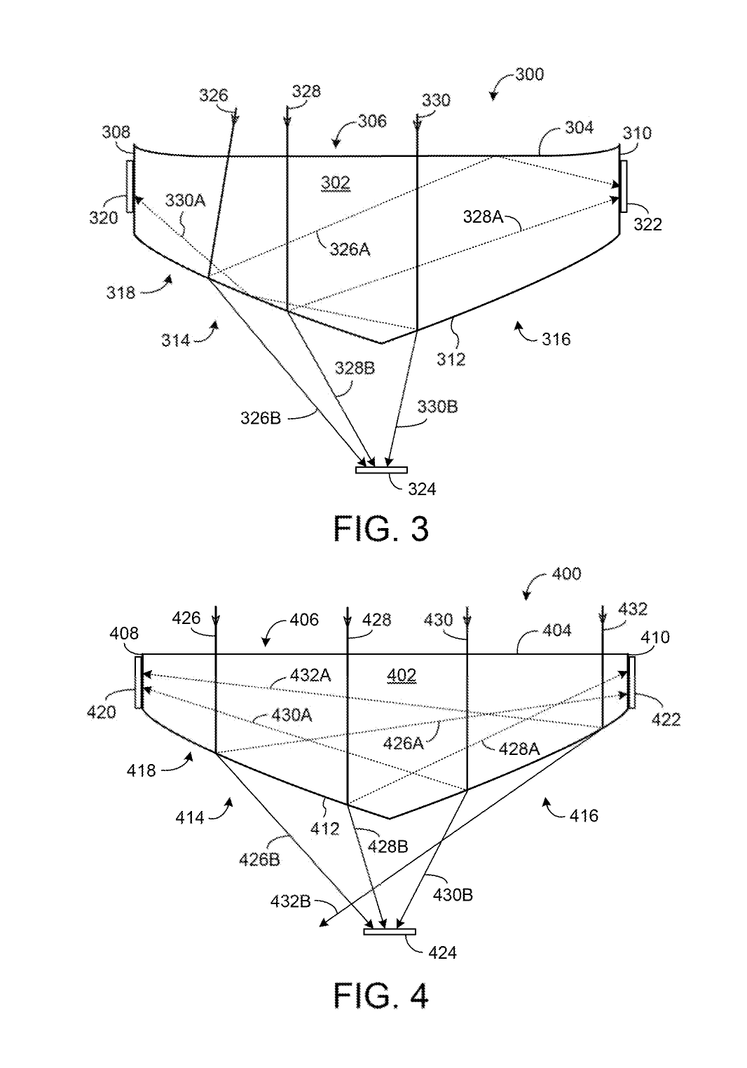

Reference is now directed to FIG. 3 which depicts an end elevation view of an optical concentrator (concentrator) 300. The concentrator 300 is illustrative and non-limiting with respect to the present teachings. Thus, other optical concentrators apparatus, devices or systems can be configured and/or operated in accordance with the present teachings. For purposes herein, the concentrator 300 can also be referred to as an optical concentrator and splitter (OCS) 300.

The concentrator 300 is formed from a solid optical material 302 such as glass, quartz, optical plastic, and so on. Other suitable materials can also be used. The concentrator 300 includes or is defined by a constant cross-sectional shape throughout a lengthwise aspect, and which is devoid of internal cavities pockets, apertures, surface intrusions, or the like. In one example, the solid optical material 302 is formed from optical plastic.

The concentrator 300 includes or is defined by a top surface 304. The top surface 304 is non-planar in form, defined by a slight upward curvature at opposite side edges. The concentrator 300 can optionally include a top surface treatment 306 borne by or formed upon the top surface 304. The top surface treatment 306 can be defined by an IR-blocking surface treatment, a UV-blocking surface treatment, an anti-reflective surface treatment, and so on. Other suitable surface treatments 306 can also be used.

The concentrator 300 also includes or is defined a pair of opposite side surfaces 308 and 310, respectively. The respective side, surfaces 308 and 310 can be planar and parallel to each other. The concentrator 300 also includes a bottom surface 312. The bottom surface 312 is defined by bilateral symmetry, having two symmetrical halves 314 and 316, respectively. Each of the half portions 314 and 316 is characterized by a surface curvature defined by an off-axis section of a parabola.

The concentrator 300 also includes a bottom surface treatment 318 borne by or formed upon the bottom surface 312. The bottom surface treatment 318 is defined by one or more dielectric material layers. One or more respective dielectric materials can be used. Non-limiting examples of dielectric materials include those described above. Other suitable materials can also be used. Thus, the bottom surface treatment 318 can be variously defined in accordance with the desired operating characteristics of the concentrator 300.

The surface treatment 318 is configured to reflect a first spectral portion or band of photonic energy that is incident to the concentrator 300 during normal operation. The bottom surface treatment 318 is further configured to pass a second spectral portion or band of such incident photonic energy through the bottom of the concentrator 300.

A photovoltaic cell 320 is supported in contact with or near to the side surface 308 of the concentrator 300. Additionally, a photovoltaic cell 322 is supported in contact with or near to the side surface 310 of the concentrator 300. Further still, a photovoltaic cell 324 is disposed below the bottom side 312 of the concentrator 300 and is spaced away there from. Each of the photovoltaic cells 320-324, respectively, is configured to generate electrical energy by direct conversion of photonic energy.

Normal, illustrative operation of the concentrator 300 is generally as follows: photonic energy, in the form of sunlight or another radiant emission, is incident to the top surface 304 of the concentrator 300. Three illustrative beams 326, 328 and 330, respectively, are depicted in the interest of clarity. Normally, the entire top surface 304 is exposed to photonic energy during operations. The respective beams 326-330 pass through the top surface 304, being subject to any top surface treatment 306 that is borne thereon, and into the solid material 302 of the concentrator 300.

Each of the beams 326-330 strikes the inside face of the bottom surface 312 at a respective location. A first spectral band of the photon is energy is reflected away from the bottom surface treatment 318. As depicted, first spectral band portions 326A and 328A of the beams 326 and 328, respectively, are internally reflected to the side surface 310. In turn, a first spectral band 330A portion of the beam 330 is internally reflected through the side surface 308.

Second spectral band portions 326B, 328B and 330B, respectively, pass through the bottom surface 312 and the bottom surface treatment 318 and are refracted toward a target location. In one example, the average wavelength of the first spectral band is lesser than the average wavelength of the second spectral band, wherein the first and second spectral bands represent mid-energy and low-energy bands, respectively.

The photovoltaic cell 320 is disposed to receive the first spectral portion 330A of the beam 330. The photovoltaic cell 322 is disposed to receive the first spectral band (or portions) 326A and 328A of the beams 326 and 328, respectively. In torr, the photovoltaic cell 324 is disposed to receive the second spectral portions 326B, 328B and 330B, respectively, of the beams 326, 328 and 330. The photovoltaic cells 320, 322 and 324 can be selected in accordance with the spectral bandwidth to which each is exposed. Photovoltaic cells or other target entities can be optimally selected in accordance with the particular characteristics of the concentrator 300.

### Third Illustrative Optical Concentrator and Splitter

Reference is directed to FIG. 4, which depicts an end elevation view of an optical concentrator (concentrators) 400. The concentrator 400 is illustrative and non-limiting with respect to the present teachings. Thus, other optical concentrators, apparatus, devices or systems can be configured and/or operated in accordance with the present teachings. For purposes herein, the concentrator 400 can also be referred to as an optical concentrator and splitter (OCS) 400.

The concentrator 400 is formed from a solid optical material 402 such as glass, quartz, optical plastic, and so on. Other suitable materials is can also be used. The concentrator 400 includes is defined by a constant cross-sectional shape throughout a lengthwise aspect, and which is devoid of internal cavities, pockets, surface intrusions, or the like

The concentrator 400 includes or is defined by a planar top surface 404. The concentrator 400 can optionally include a top surface treatment 406 borne by or formed upon the top surface 404. The top surface treatment 406 can be defined by an IR-blocking surface treatment, a UV-blocking surface treatment, an anti-reflective surface treatment, and so on. Other suitable surface treatments 406 can also be used.

The concentrator 400 also includes or is defined a pair of opposite side surfaces 408 and 410, respectively. The respective side surfaces 408 and 410 can be planar and parallel to each other. The concentrator 400 also includes a bottom surface 412. The bottom surface 412 is defined by two symmetrical halves 414 and 416, respectively. Each of the half portions 414 and 416 is characterized by a surface curvature defined by an off-axis section of a parabola.

The concentrator 400 also includes a bottom surface treatment 418 borne by or formed upon the bottom surface 412. The bottom surface treatment 418 is formed from or defined by one or more layers of one or more respective dielectric materials. Non-limiting examples of dielectric materials include those described above.

The surface treatment 418 is configured to reflect a first spectral portion or band of photonic energy that is incident to the concentrator 400 during normal operation. The bottom surface treatment 418 is further configured to pass a second spectral portion or band of such incident photonic energy through the bottom of the concentrator 400.

A photovoltaic cell 420 is supported in contact with or near to the side surface 408 of the concentrator 400. Additionally, a photovoltaic cell 422 is supported in contact with or near to the side surface 410 of the concentrator 400. Further still, a photovoltaic cell 424 is disposed below and apart from the bottom side 412 of the concentrator 400. Each of the photovoltaic cells 420-424, respectively, is configured to generate electrical energy as described above.

Normal, illustrative operation of the concentrator 400 is generally as follows: photonic energy is incident to the top surface 404 of the concentrator 400. Four illustrative beams 426, 428, 430 and 432, respectively, are depicted in the interest of clarity. Normally, the entire top surface 404 is exposed to photonic energy during operations. The respective beams 426-432 pass through the top surface 404 and are subject to any top surface treaty ent 406 that is borne thereon, and into the solid material 402.

Each of the beams 426-432 strikes the inside face of the bottom surface 412 at a respective location. A first spectral band of the photonic energy is reflected away from the bottom surface treatment 418. As depicted, first spectral band portions 426A and 428A of the beams 426 and 428 are internally reflected through the side surface 410. In turn, first spectral band portions 430A and 432A of the beams 430 and 432 are internally reflected through the side surface 408. It is noted that internal reflections off of the inside of the top surface 404 do not occur during normal operation of the concentrator 400. A second spectral band of the photonic energy passes through the bottom surface 412 and the bottom surface treatment 418 and is refracted toward a target location.

The photovoltaic cell 420 is disposed to receive the first spectral band portions 430A and 432A. The photovoltaic cell 422 is disposed to receive the first spectral band portions 428A and 428A. In turn, the photovoltaic cell 424 is disposed to receive the second spectral band portions 426B, 428B and 430B, respectively, of the beams 426, 428 and 430. The photovoltaic cells 420, 422 and 424 can be selected in accordance with the spectral bandwidth to which each is exposed.

It is noted that the second spectral band 432B of the beam 432 is refracted such that it does not strike the photovoltaic cell 424, as depicted. Thus, a certain percentage of loss can occur during some normal operations.

### Illustrative System

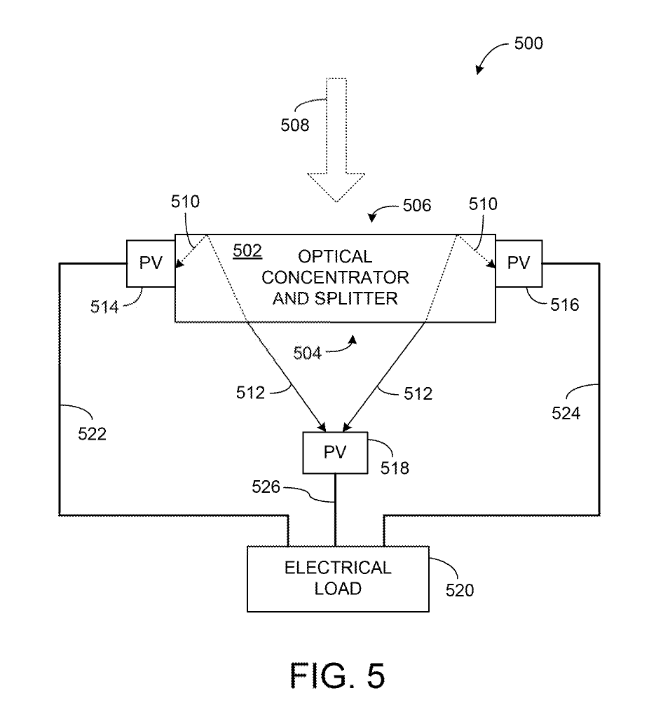

Attention is no turned to FIG. 5, which depicts a block diagram of a system 500 according to another example of the present teachings. The system 500 is illustrative and non-limiting in nature, and other systems, devices and apparatus are contemplated by the present teachings.

The system 500 includes an optical concentrator and splitter (OCS) 502. The OCS 502 is formed from a solid optical material and bears a dielectric surface treatment 504 on a bottom side thereof. The OCS 502 can optionally include a top surface treatment 506 on a top surface thereof. The OCS 502 is configured to receive incident photonic energy 508 and to split that energy into two distinct spectral bands or portions.

The first spectral band 510 is concentrated by way of internal reflections toward opposite side surfaces. The second spectral band 512 passes through the dielectric surface treatment 504 and is refracted toward a target location beneath the OCS 502.

The system 500 further includes respective photovoltaic cells 514 and 516, which are disposed to receive respective shares of the first spectral band 510. The system 500 also includes a photovoltaic cell 518 disposed to receive the second spectral band 512. Each of the photovoltaic cells 514-518 is configured to derive electrical energy from photonic energy incident thereto by way of direct conversion.

The system 500 further includes an electrical load 520 coupled to receive electrical energy from the photovoltaic cells 514-518 by way of respective electrical circuit pathways 522, 524 and 526. The electrical load 520 can be defined by any suitable device, apparatus or system. Non-limiting examples of the electrical load 520 include cellular or satellite communications equipment, a computer, a global positioning system (GPS) receiver, a storage battery, a power conditioning system, an electrical inverter, and so on. Other electrical loads 520 can also be used.

The system 500 is illustrative of elements and operations contemplated by the present teachings. As such, the system 500 is broad and conceptual in its intended representation.

### Illustrative Method

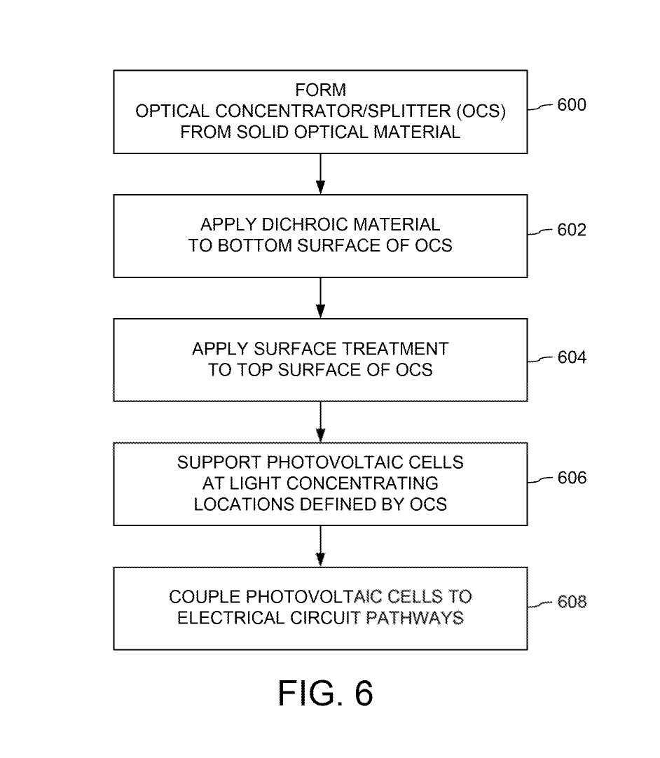

Reference is now made to FIG. 6, which depicts a flow diagram of a method according to the present teachings. The method of FIG. 6 includes particular operations and order of execution. However, other methods including other operations, omitting one or more of the depicted operations, and/or proceeding in other orders of execution can also be used according to the present teachings. Thus, the method of FIG. 6 is illustrative and non-limiting in nature. Reference is made to FIGS. 1 and 5 in the interest of understanding FIG. 6.

At 600, an optical concentrator and splitter is formed from solid optical material. For purposes of a present example, it is assumed that an optical concentrator and splitter 100 is formed from solid optical glass. The OCS 100 is defined by a planar top surface 104, opposite side surfaces 108 and 110, and a non-planar bottom surface 112. Each half portion 114 and 116 of the bottom surface 112 has a cross-sectional shape (or surface contour) in accordance with an off-axis section of a parabola.

At 602, dielectric material is applied to the bottom surface of the optical concentrator and splitter. For purposes of the present example, a surface treatment 118 is applied to or formed upon the bottom surface 112 of the OCS 100. The surface treatment 118 can be formed from any number of layers of any number of dielectric materials. The surface treatment 118 defines a photonic energy spectral band splitting characteristic or “pass-band” for the OCS 100 in accordance with the particular dielectric materials used and their layering arrangement.

At 604, a surface treatment is applied to the top surface of the optical concentrator and splitter. For purposes of the present example, an anti-reflective surface coating or material is formed on the top surface 104 of the OCS 100. Other surface treatments 104 can also be used in other examples.

At 606, photovoltaic cells are supported at light concentrating locations defined by the optical concentrator and splitter. For purposes of the present example, photovoltaic cells 120, 122 and 124 are supported at respective locations so as to receive a concentrated spectral band of photonic energy. Specifically, the photovoltaic cells 120 and 122 are supported so receive a first spectral band of energy at the opposite side surfaces 108 and 110, respectively. In turn, the photovoltaic cell 124 is supported to receive a second spectral band of energy at a location beneath and spaced apart from the bottom surface 112.

At 608, the photovoltaic cells are coupled to electrical circuit pathways. For purposes of the present example, the photovoltaic cells 120-144 are coupled to electrical circuit pathways (conductive traces wires) so as to define a photovoltaic array. Such electrical circuit pathways (e.g., 522-526) can electrical couple the photovoltaic array to a electrical load (e.g., 520), or to each other in a series and/or parallel arrangement. It is to be understood that the method described above can be suitably varied in accordance with the present teachings.

In general, and without limitation, the present teachings contemplate light concentrators and splitters (LCS) for use with solar energy or other sources of photonic emission. An LCS has a main portion formed from a solid optical material such as glass, optical plastic, and so on. Respective top, side and bottom surfaces are defined by the LCS, as well as end surfaces. The bottom surface has two symmetrical half portions, each having a cross-sectional shape in accordance with an of section of a parabola.

A dielectric surface treatment is borne by or formed upon the bottom surface so as to define a band of photonic energies that is internally reflected within the LCS and another, distinct band of photonic energies that is passed or transmitted there through. An optional surface treatment can be borne by or formed upon the top surface. Such optional surface treatment can be characterized as a UV-blocker, an IR-blocker, an anti-reflective coating, and so on.

The photonic energy, typically sunlight, is received through the top surface and is subject to or conditioned by the top surface treatment, if any. The received photonic energy strikes the dielectric surface treatment on the inside of the bottom surface and a first spectral band is reflected away there from. This first spectral band is concentrated by way of internal reflections and is directed in about equal quantities outward through opposite side surfaces of the LCS. A second spectral band passes through the dielectric surface treatment and is concentrated by way of refraction onto a target location (strip-like region) beneath and away from the bottom surface of the LCS.

Target entities, such as photovoltaic coifs, fluid-filled thermal absorption conduits, and the like, are disposed to receive the concentrated photonic energy transmitted outward from the LCS. These target entities can be specifically selected in accordance with the spectral band that each receives. The present teachings contemplate the optimization of the operating characteristics of respective light concentrators and splitters in accordance with the particular target entities to be used therewith.

In general, the foregoing description is intended to be illustrative and not restrictive. Many embodiments and applications other than the examples provided would be apparent to those of ordinary skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claim.

What is claimed is:

1. An apparatus, comprising:
a solid optical material formed to define a top surface and a pair of opposite side surfaces and a non-planar bottom surface; and
one or more dielectric materials applied to the non-planar bottom surface thus defining a coated bottom surface, the apparatus configured to receive photonic energy through the top surface and to concentrate a first spectral band thereof through the opposite side surfaces, the apparatus further configured to concentrate a second spectral band of the photonic energy through the coated bottom surface.

2. The apparatus according to claim 1, at least some of the first spectral band being concentrated through the opposite side surfaces by way of internal reflections off of the top surface.

3. The apparatus according to claim 1, the apparatus further including at least an anti-reflective, an infra-red blocking, or an ultra-violet blocking surface treatment on the top surface.

4. The apparatus according to claim 1, the first spectral band being of relatively shorter wavelengths than the second spectral band.

5. The apparatus according to claim 1, the non-planar bottom surface defined by bilateral symmetry, each half of the bilateral symmetry having a cross-sectional contour in accordance with an off-axis section of a parabola.

6. The apparatus according to claim 1 further comprising:
a first photovoltaic cell disposed to receive at least a portion of the concentrated first spectral band of the photonic energy; and
a second photovoltaic cell disposed to receive at least a portion of the concentrated second spectral band of the photonic energy.

7. The apparatus according to claim 6, the first photovoltaic cell and the second photovoltaic cell electrically coupled to provide electrical energy to an electrical load entity.

8. A solar energy device, comprising:
an optical concentrator and splitter formed from a solid optical material, the optical concentrator and splitter configured to concentrate a first spectral band of photonic energy onto a pair of first target locations, the optical concentrator and splitter configured to concentrate a second spectral band of photonic energy onto a second target location distinct from the first;
photovoltaic cells disposed at the first target locations; and
photovoltaic cells disposed at the second target location.

9. The solar energy device according to claim 8, the first target locations being about coincident with respective opposite side surfaces of the optical concentrator and splitter, the second target location being spaced apart from a bottom surface of the optical concentrator and splitter.

10. The solar energy device according to claim 8, the optical concentrator and splitter including a non-planar bottom surface, the bottom surface bearing dielectric materials defining a surface treatment, the first and second spectral bands respectively defined in accordance with the surface treatment.

11. The solar energy device according to claim 8, the optical concentrator and splitter configured to receive incident photonic energy by way of a top surface thereof.

12. The solar energy device according to claim 11, the top surface being defined by a non-planar shape.

13. A method, comprising
forming a solid optical material to define a top surface and a non-planar bottom surface and a pair of opposite side surfaces;
forming a surface treatment of dielectric material on the bottom surface thus defining a coated surface;
supporting respective photovoltaic cells parallel to each of the side surfaces; and
supporting photovoltaic cells beneath acrd spaced apart from the bottom surface.

14. The method according to claim 13, the non planar bottom strata formed to define symmetrical half portions, each half portion having a cross-sectional shape defined by an off-axis section of a parabola.

15. The method according to claim 13, the top surface having a non-planar planar surface contour.
